(19) United States
(12) Patent Application Publication
(10) Pub. No.: US 2002/0053915 A1
(43) Pub. Date: May 9, 2002

(54) Electrophysiology configuration suitable for high throughput screening of compounds for drug discovery

(76) Inventors: Charles David Weaver, Wallingford, CT (US); Alastair Binnie, New Haven, CT (US)

Correspondence Address: STEPHEN B. DAVIS, BRISTOL-MYERS SQUIBB COMPANY, PATENT DEPARTMENT, P O BOX 4000, PRINCETON, NJ, 08543-4000, US

(21) Appl. No.: 09/900,627

(22) Filed: Jul. 6, 2001

Related U.S. Application Data
(60) Provisional application No. 60/216,903, filed on Jul. 7, 2000.

(51) Int. Cl. G01R 27/00

(52) U.S. Cl. 324/600

(57) ABSTRACT

The present invention provides apparatuses for measuring cell membrane resistance, conductance, potential, and capacitance, which can be used to determine cellular electrical activity. More specifically, the present invention provides automated apparatuses that are designed for high-throughput analysis of various compounds, ligands, and cell processes that modulate cellular electrical properties (e.g., cell membrane conditions). Such automated apparatuses can be used for the precise determination of ion channel activity, and for the rapid identification of compounds, ligands, or processes that alter this activity. The present invention also provides methods for measuring cellular electrical properties utilizing the apparatuses provided herein.

### RELATED APPLICATIONS

This application claims the benefit of U.S. patent application Ser. No. 60/216,903 filed Jul. 7, 2000, which is hereby incorporated by reference in its entirety.

### FIELD OF THE INVENTION

The present invention relates to apparatuses for measuring cell membrane potential, resistance, conductance, and capacitance, which can be used to measure ion channel activity, ion transporter activity, or changes in the properties of the cell membrane caused by cell-cell interactions, cell-cell fusion, viral infection, endocytosis, exocytosis, membrane recycling, or membrane-ligand interaction. Specifically, the present invention relates to apparatuses that can be employed for high-throughput analysis of various chemicals, compounds, ligands, or cell processes that modulate cellular electrical properties. Such apparatuses can be used for the precise determination of ion channel activity, and for the rapid identification of chemicals, compounds, ligands, or processes that alter this activity. The present invention also relates to methods for measuring cell electrical properties and utilizing the apparatuses provided herein.

### BACKGROUND OF THE INVENTION

Ion channels are transmembrane proteins that form pores in a biological membrane and allow ions to pass from one side to the other (reviewed in B. Hille (Ed), 1992, Ionic Channels of Excitable Membranes 2^{nd} ed., Sinauer, Sunderland, Mass.). Although certain ion channels are open under all physiological membrane conditions (so-called leak channels), many channels have ‘gates’ that open in response to a specific stimulus. As examples, voltage-gated channels respond to a change in the electric potential across the membrane, mechanically-gated channels respond to mechanical stimulation of the membrane, and ligand-gated channels respond to the binding of specific molecules. Various ligand-gated channels can open in response extracellular factors, such as a neurotransmitters (transmitter-gated channels), or intracellular factors, such as ions (ion-gated channels), or nucleotides (nucleotide-gated channels). Still other ion channels are modulated by interactions with proteins, such as G-proteins (G-protein coupled receptors).

Most ion channel proteins mediate the permeation of one predominant ionic species. For example, sodium (Na⁺), potassium (K⁺), chloride (Cl⁻), and calcium (Ca²⁺) channels have been identified. In addition, ion channels that are specific for the permeation of one ion can be further divided into various subcategories or channel types, based on their response to electrical and/or chemical (pharmacological) stimuli. In particular, voltage-gated calcium channels include L-type, N-type, T-type, R-type, and P/Q-type channels that display different properties, pharmacology, and tissue distribution (G. Varadi et al., 1999, Crit. Rev. Biochem. Mol. Biol. 34:181-214). Notably, ion channels differ from other types of ion transporter proteins. For instance, ion channels conduct ions ‘down’ a electrochemical gradient whereas other transporter proteins can conduct ions ‘uphill’ against a concentration gradient (Hille, supra).

Ion channels are responsible for creating the cell membrane potential, which is the difference in the electrical charge on the opposite sides of the cell membrane (reviewed in B. Alberts et al., 1994, Molecular Biology of the Cell, 3^{rd} ed, Garland Publishing, Inc., New York, N.Y.). In animal cells, Na⁺-K⁺ ATPases keep the intracellular concentration of Na⁺ low, and the intracellular concentration of K⁺ high. In opposition to the Na⁺-K⁺ ATPases, K⁺ leak channels allow the K⁺ ions to travel down the K⁺ concentration gradient and out of the cells. Other ion transporters are responsible for maintaining ionic gradients, such as Cl⁻ ion gradients (Y. Kakazu et al., 1999, Neurosci. 19:2843-51). In this way, several ion channels, including Na⁺, K⁺, and Cl⁻ channels, collectively contribute to the formation of the cellular membrane potential.

Voltage-gated ion channels are responsible for generating cell membrane action potentials in electrically excitable cells, including most muscle and nerve cells (B. Alberts, supra). An action potential is triggered by cell membrane depolarization, which is caused by an influx of Na⁺ through the voltage-gated Na⁺ channels. Voltage-gated Ca²⁺ channels can also generate an action potential in some electrically active cells. It should be noted, however, that ion channels are not limited to excitable cells. In fact, voltage-gated Na⁺, K⁺, or Ca²⁺ channels are present in certain cell types that are not normally considered to be excitable (B. Alberts, supra).

As indicated above, ion channel activity can be modulated by various ligands and proteins, including neurotransmitters, nucleotides, and G-proteins. Such ligands have been shown to bind to ligand-gated ion channels, and thereby alter ion channel activity. In particular, G-protein-gated K⁺ channel activity is modulated by interactions with a G-protein bound to its cognate G-protein-linked receptor (N. Dascal, 1997, Cell Signal 9:551-73; J. L. Sui et al., 1999, Adv. Second Messenger Phosphoprot. Res. 33:179-201). In addition, voltage-gated Ca²⁺ channels are regulated by a G-protein dependent pathway (G. W. Zamponi et al., 1998, Curr. Opin. Neurobiol. 8:351-6). It should be noted that cell membrane conditions (e.g., electrical capacitance) can also be modulated by various cell processes, including cell-cell interactions, cell-cell fusion, viral infection, endocytosis, exocytosis, membrane recycling, and membrane-ligand interaction (K. Lollike et al., 1999, J. Immunol. Methods 232:111-20).

Many chemicals, compounds, and ligands are known to affect ion channel activity. Moreover, agents that modulate ion channel activity can be formulated into pharmaceutical compositions that may be used in the treatment of various diseases, injuries, or conditions (S. A. N. Goldstein et al., 1996, Neuron 16:913-919). For example, agents that modulate the activity of Ca⁺² channels may be used in the treatment of epilepsy, anxiety, and Alzheimer's disease. In addition, agents that modulate the activity of Na⁺ channels may be used to treat muscle spasms, torticollis, tremor, learning disorders, brain cancer, and Alzheimer's disease. Agents that block slow Na⁺ channels may be used as local anesthetics. Agents that modulate epithelial Na⁺ channels may be used in the treatment of cystic fibrosis, asthma, and hypertension. Furthermore, agents that modulate the activity of K⁺ channels may be used counteract the damaging effects of anoxic and ischemic disorders and hypertension, and to protect red blood cells against damage in malaria and sickle-cell disease (J. R. Enfeild, et al., 1995, Pharmaceutical News 2:23-27).

Ion channel activity can be measured using a technique termed patch-clamp analysis (E. Neher et al., 1978, Pflugers Arch. 375:219-28; O. P. Hamill et al., 1981, Nature 294:462-4). In accordance with this technique, a cell is attached to the tip of a micropipette, and suction is applied. If a high-resistance seal equivalent to 1-10 gigaohms (10⁹ ohms) is established between the micropipette and a region of the cell membrane, an electric current flowing though the micropipette is identical with a current flowing through the membrane sealed to the tip of the micropipette. This so-called gigaseal makes it possible to make high-resolution current measurements if a known voltage is applied across the membrane. In this way, patch-clamp analysis can be used to determine the electrical conditions of the membrane, and the corresponding activity of the ion channels.

Patch-clamp analysis can be applied to the entire cell membrane (whole-cell mode) or a small region of the cell membrane (excised-patch or cell-attached modes). During patch or whole-cell analysis, the activity of individual ion channel subtypes can be further resolved by placing a “voltage-clamp” across the membrane. The voltage-clamp imposes a voltage gradient across the membrane through the use of a feedback loop, and limits the overall ion channel activity to allow resolution of discrete ion channel subtypes. In such experiments, the time resolution is usually in the sub-millisecond range. In addition, current-clamp or lock-in amplifier techniques can be used to measure cellular transmembrane potential or changes in cellular capacitance, respectively. Such techniques use similar instrumentation and conditions for establishing electrical access to the cells as the patch-clamp technique.

The development of the patch-clamp technique has allowed significant advancement in biological and medical research. In particular, patch-clamp techniques have allowed the study of ion channel responses to various test agents. Moreover, patch-clamp techniques are superior to other types of membrane analysis (e.g. fluorescence-based membrane analysis), since patch-clamp recordings are more sensitive and show higher resolution than other techniques. However, patch-clamp and related forms of analysis have not been successfully adapted for extremely rapid and accurate high-throughput screens, until now. Such high-throughput screens would be invaluable for the search and identification of agents that modulate ion channel activity. In turn, such agents would be useful for the treatment of various diseases, injuries, and conditions (see above). However, standard patch-clamp techniques are limited to testing a small number of agents per experiment. In addition, the standard techniques are further limited by the slow rate of sample compound change, and the spatial precision required by the patch-clamp pipettes. Accordingly, there have been several attempts to increase the throughput capacity of patch-clamp analysis.

The WO96/13721 reference describes a patch-clamp apparatus utilizing an autosampler, which is normally used for HPLC analysis. The autosampler is designed to reduce the patch-clamp fluid volume requirements and to increase the rate of fluid change for the cells and patches. The problem with this apparatus is that it semi-automates the apparatus for test compound delivery, but it does not automate the apparatus for patch-clamp analysis. Specifically, the WO96/13721 apparatus still requires linear processing of data (i.e., data is collected from only one cell at a time), and is therefore limited to a relatively slow speed of testing agents. Thus, the WO96113721 apparatus cannot be considered an actual high-throughput apparatus.

Another reference, WO99166329, describes an automated apparatus for analyzing biological membranes that contain ion channels or transporters of interest and are adhered with high resistance seals to a porous or perforated substrate. The WO99/66329 apparatus is designed for high-throughput screens for agents that modulate ion channel or ion transporter activity. In particular, the apparatus can be used to measure the resistance and conductance of the biological membrane in the presence of one or more test agents. Although this apparatus overcomes some of the problems of the WO96/13721 apparatus, it has notable disadvantages. Specifically, in order to obtain measurements of cell membrane resistance values, the WO99/66329 apparatus requires that each and every pore in the substrate is sealed with a biological membrane. An open pore or ‘hole’ in the substrate (i.e. caused by a missing or incompletely attached cell membrane) renders the apparatus inoperative.

Thus, there is a need in the art for apparatuses and methods for electrophysiological analysis that can be used for making rapid, robust, and accurate measurements of cell membrane conditions. Such apparatuses and methods can be adapted for high-throughput screening of agents or cellular processes that modulate ion channel or transporter activities. The present invention therefore provides such methods, as well as the apparatuses for performing such methods.

### SUMMARY OF THE INVENTION

It is an object of the present invention to provide apparatuses for measuring ion channel activity. As disclosed herein, the apparatuses can be used to measure cell membrane potential, and electrical resistance, conductance, and capacitance, which can be used to determine cell ion channel activity or cell membrane activity (e.g., cell-cell interactions, cell-cell fusion, viral infection, endocytosis, exocytosis, membrane recycling, and membrane-ligand interaction).

One apparatus provided by the present invention comprises a porous Cell Support Membrane component that is adapted to hold cells. The top (cis) surface of the Cell Support Membrane component is in contact with the cells, and faces a ‘ground’ electrode. The bottom (trans) surface of the Cell Support Membrane component faces a current-passing/voltage-measuring electrode. Both cis and trans surfaces of the Cell Support Membrane component are in contact with an electrolyte solution. Preferably, the Cell Support Membrane component comprises a first layer comprising a porous, non-conductive, material, and a second layer comprising a non-porous, non-conductive, sealant material. More preferably, the pores of the first layer of the Cell Support Membrane are sized to contact individual cells, and are capable of forming tight seals with the cell membrane of the contacted cells. Most preferably, the first layer of the Cell Support Membrane component includes cell attachment sites, which circumscribe the pores. Cell attachment sites comprise a material, substance, and/or texture that facilitates (i.e., encourages) attachment, whereas surfaces circumscribing cell attachment sites comprise a material, substance, and/or texture that inhibits (i.e., discourages) attachment.

Another apparatus provided by the present invention comprises a microfabricated chip component that is adapted to hold cells, which can be used to determine cell membrane resistance, conductance, potential, and capacitance. Preferably, the Microchip component comprises silicon, glass, or polymer materials, and is embedded with a ground electrode and an electrode lead/signal modifying circuitry. More preferably, the cis surface of the Microchip component comprises one or more features to promote cell attachment at specific sites (e.g., pits, pins, textures, or cell-adhesive substances), while the areas surrounding these sites comprise a material, substance, and/or texture to inhibit cell attachment. Most preferably, an independent electrode is attached to each cell attachment site of the Microchip component, and is connected to the electrode lead/signal modifying circuitry.

It is yet another object of the present invention to provide an automated apparatus for measuring ion channel activity. The automated apparatus comprises the disclosed Cell Support Membrane or Microchip components that are adapted for high-throughput analysis of chemicals, compounds, ligands, or processes that modulate membrane conditions (e.g., ion channel activity or membrane capacitance).

It is still another object of the present invention to provide methods for measuring cellular ion channel activity, or transporter activity, utilizing the Cell Support Membrane and/or Microchip components described herein. Such methods are useful for identifying compounds that modulate the activity of ion channels and transporters.

It is a further object of the present invention to provide methods for measuring cell processes (e.g., cell-cell interaction, cell-cell fusion, viral infection, endocytosis, exocytosis, membrane recycling, and membrane-ligand interaction) utilizing the Cell Support Membrane and/or Microchip components described herein.

It is another object of the present invention to provide methods for the high-throughput screening of compounds or cell processes that modulate cell membrane conditions (e.g., ion channel activity or electrical capacitance). Such methods utilize the automated apparatuses as disclosed herein.

It is yet another object of the present invention to provide methods of obtaining real-time measurements of cell membrane permeability utilizing the apparatuses provided herein. Such methods can be used to study drug trafficking, for example, in Caco-2 cells.

Additional objects and advantages afforded by the present invention will be apparent from the detailed description and exemplification hereinbelow.

### DESCRIPTION OF THE FIGURES

The appended drawings of the figures are presented to further describe the invention and to assist in its understanding through clarification of its various aspects.

FIG. 1 illustrates an example of a porous, non-conductive Cell Support Membrane (CSM) mounted in a chamber. The membrane separates a ground electrode and a measuring electrode. Cells added to the top (cis) surface of the Cell Support Membrane to occlude the pores of the membrane and establish a tight (˜1 G Ohm) seal. This arrangement allows the direct measurement of the electrical properties of the cells utilizing cell-attached recording techniques. Whole-cell measurements can be obtained by permeabilization of the cell by the addition of antibiotic or detergent to the bottom (trans) surface of the Cell Support Membrane, or by electropermeabilization. Inside-out patch measurements can be obtained by exposing the cis surface of the Cell Support Membrane to an air-water interface.

FIG. 2 illustrates an example of an upright laser scanning microscope used to selectively destroy a non-conductive sealant layer underneath a porous Cell Support Membrane surface with attached cells. Cells are selected using epifluorescent or transmitted light imaging, based on cell morphology or the expression of a marker such as green fluorescent protein. The non-conductive sealant layer underneath the selected cells is ablated by a focused laser beam. The electrical properties of the cells are then measured using the techniques described for FIG. 1.

FIG. 3 illustrates three Microchip configurations that are designed for making independent or simultaneous electrical measurements of one or more cells. Each Microchip configuration requires the formation of tight (˜1 G Ohm) seals with the cells on the cis surface of the Microchip. Cell-attached, inside-out or whole-cell mode measurements can be obtained as described in FIG. 1. Each configuration contains a cell attachment area with an embedded independent measuring electrode and a local common ground. The areas outside of the cell attachment areas are coated with a substance to discourage cell attachment. The Pit configuration utilizes a recessed area that is approximately the same size as a single cell. The inside of the pit is coated with a substance to promote cell attachment and seal formation. In the Pin configuration, the measuring electrode projects out of the cell attachment site to penetrate the cell membrane. In the Texture configuration, the cell attachment site is textured to promote cell attachment and seal formation.

### DETAILED DESCRIPTION OF THE INVENTION

The present invention provides apparatuses and methods that allow rapid and accurate measurements of membrane resistance, conductance, potential, and capacitance in cells. Such apparatuses and methods can be utilized for high throughput screening of compounds, ligands, or cell processes for effects on cell membrane activity, for example, ion channel activity and changes in cell membrane capacitance resulting from such processes such as endocytosis, exocytosis, and cell-cell fusion. The present invention differs from currently available electrophysiology apparatuses in that it removes the requirement for the high degree of spatial precision needed for the positioning of the patch-clamp, intracellular electrodes, or cells. Certain embodiments of the present invention also allow independent measurements of the electrical conditions for each cell, and process these measurements in parallel. This allows both faster and more accurate readings of electrical conditions than possible with previously described techniques. Thus, the present invention represents an important advancement in our ability to apply electrophysiology techniques to drug discovery strategies.

Cell Support Membrane components

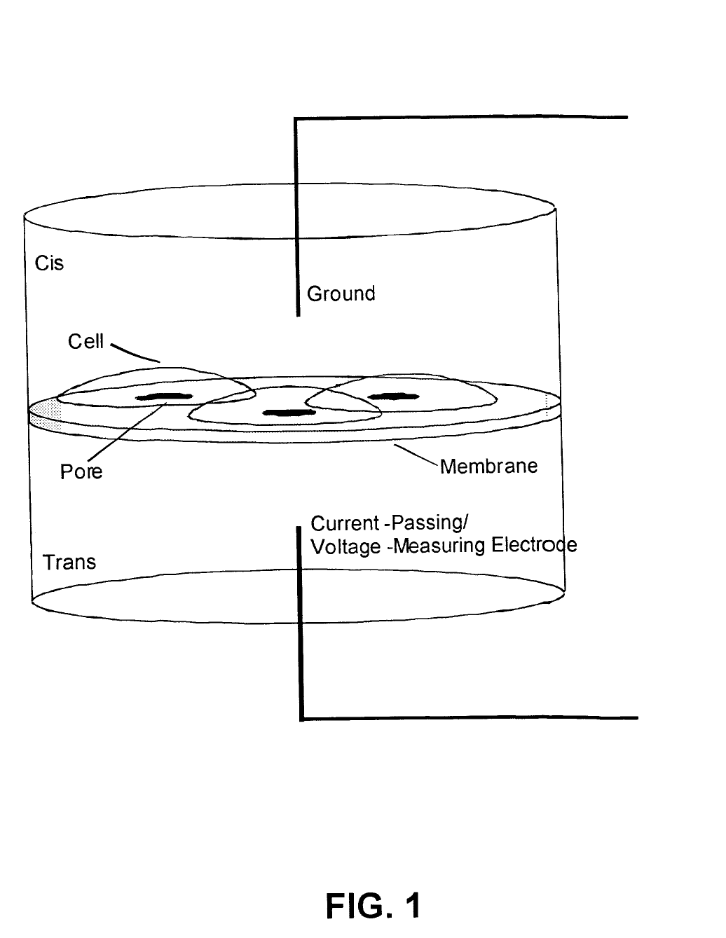

In accordance with the present invention, the Cell Support Membrane and Microchip components are adapted to hold cells and allow measurements of cellular electrical properties (e.g., cell membrane conditions). Such components comprise a ‘cis’ surface, which faces the cells, as well as a ‘trans’ surface, which faces away from the cells (FIG. 1). Preferably, the Cell Support Membrane and Microchip components are manufactured from non-conductive materials, including but not limited to, glass, plastic, rubber, polytetraflurotethylene (PTFE), PTFE/glass, and/or polyethylene terephthalate (PETP), and polycarbonate. In particular, PTFE and PETP materials have high dielectric constants, and can be manufactured into extremely thin sheets, which reduce the minimum series resistance in the apparatus.

The Cell Support Membrane component of the present invention is preferably perforated, and can range in size from 1-2 mm to 1-10 cm. Preferably, the Cell Support Membrane component is 2-5 mm in diameter. The pores on the Cell Support Membrane component are designed to be smaller in diameter than the cells to be placed on the component. The pores are thereby able to form tight seals (i.e., optimal resistance values of greater than 0.5 gigaohms) with the cell membranes of the attached cells. Preferably, the pores are 0.1-5 μm in diameter. More preferably, the pores are 0.2-2 μm in diameter. Most preferably the pores are 0.1-0.5 μm in diameter. The number of pores on the Cell Support Membrane component is optimized to allow a statistically acceptable number of parallel recordings. For some purposes, it may be preferable to construct a Cell Support Membrane component to display 1 pore. Preferably, the Cell Support Membrane displays ≧4 pores. More preferably, the Cell Support Membrane displays 4-10 pores. The pores in the Cell Support Membrane can be produced by various methods, including laser incision, photo-etching, casting, particle bombardment, and physical piercing of the Cell Support Membrane surface. Alternately, highly porous materials for some embodiments of the invention can be obtained from commercial sources (e.g., porous rubber, Corning Costar® Transwell Cell Culture Inserts (Fisher Scientific Co., Pittsburgh, Pa.), Becton Dickinson Cell Culture Inserts (Becton Dickinson, Franklin Lakes, N.J.), and MILLIPORE Millicells Cell Culture Inserts (MILLIPORE, Bedford, Mass.).

Because it is essential that each pore of the Cell Support Membrane component is sealed with a cell membrane, the present invention provides several embodiments of the Cell Support Membrane that are designed to increase the probability of the formation of a cell/pore seal. Preferably, the Cell Support Membrane includes cell attachment sites, which circumscribe the pores and comprise a material, substance, texture, and/or an electrical or chemical attractant that facilitates cell attachment and seal formation. Such cell attachment sites are sized to accommodate the cells to be placed on the Membrane (i.e., 1-30 μm in diameter). Specifically, cell attachment sites can be 15-20 μm in diameter to accommodate mammalian cells (e.g., CHO cells). In contrast, the surfaces of the Cell Support Membrane surrounding the cell attachment sites comprise a material, substance, and/or texture that inhibits cell attachment. Materials that facilitate cell attachment include standard tissue culture plastic treated with plasma or one or more substances comprising molecules such as poly-D-lysine, poly-L-lysine, collagen, fibronectin, gelatin, and/or other extracellular matrix proteins. Materials that inhibit cell attachment include plastics treated with hydrophobic substances comprising molecules such as C18 silanes, silicones, and Teflon®. Such materials and substances and are well known in the art and are commercially available. See, for example, Corning Costar® Transwell-COL collagen-treated Cell Culture Inserts (Fisher Scientific Co.), and Becton Dickinson BD BioCoat® collagen I-, polylysine-, or gelatin-treated Cellware (Becton

In addition, cells can be attracted to the pores of the Cell Support Membrane component by an electrical or chemical attractant. For example, a chemoattractant, such as a cell growth factor, chemokine, or nutrient can be applied to the pore or to the solution bathing the trans surface of the pore. In this way, the chemoattractant can diffuse through the pore and create a concentration gradient centered on the pore. This concentration gradient will promote the migration of the cells to cover and partially penetrate the pore, thus facilitating the formation of a gigaseal. Alternatively, an electric field can be applied across the pore, in order to attract the cells by electrophoresis (J. Bauer, 1999, J. Chromatogr. B. Biomed. Sci. Appl. 722:55-59). In particular, an electric field of 100 mV can be applied to attract mammalian cells. However, an optimal electric field may be determined for the specific cell-type to be studied. To prevent the cells from settling (via gravity) onto a site outside the area of a pore during electrophoresis, the cells can be suspended in an isotonic medium that is the same density of the cells. For example, an isotonic medium containing 140 mM NaCl, 2.5 mM KCl, 2 mM CaCl₂, 1 mM MgCl₂, 10 mM glucose, 10 mM HEPES pH 7.3 (˜290 mOsm) containing suspensions with low osmotic activity such as percoll, ficoll, or metrizamide can be used. A suitable density gradient can be determined for a specific cell-type and experiment as required. In particular, a density gradient containing 1.07-1.10 g/ml percoll is preferably used for mammalian (e.g., CHO) cells.

Following cell attachment, the Cell Support Membrane component of the present invention can be examined electrically by monitoring resistance across the cell membrane. If one or more pore remains open or partly open, it can be filled by the addition of Composition A onto the one side of the pore, and the addition of a Composition B onto the opposite side of the pore. These components can then react inside the pore to form a plug with high electrical resistance, and thereby seal the pore. For example, the Composition A may be an enzyme and Composition B may be the non-cell permeant substrate for the enzyme. The enzyme and the substrate will react to form an insoluble, non-conductive precipitate or polymer, thus occluding the pore. For example calf alkaline phosphatase can be used as Composition A and BCIP (5-bromo-4-chloro-3′-indolyphosphate p-toluidine salt) and NBT (nitro-blue tetrazolium) can used as Composition B. In particular, 1 U/ml calf intestinal alkaline phosphatase, 165 μg/ml BCIP, and 330 μg/ml NBT can be used. However, optimal concentrations of the enzyme and the substrate(s) can be determined for any given experiment. As another example, Composition A may be a non-cell permeant compound that reacts with a non-cell permeant Composition B to form a non-conductive precipitate or polymer that occludes the pore.

In a further embodiment of the present invention, the Cell Support Membrane comprises two components, including a layer comprising porous, non-conductive material as described herein, and a layer comprising a non-porous, non-conductive sealant material. The sealant material can comprise any non-conductive substance that is insoluble in the solution bathing the cells, including the polymers used to manufacture the porous layer. Preferably, the sealant comprises spun applied polyester. More preferably, the sealant layer is capable of being removed, solubilized, or made conductive at regions that contact the pores of the porous layer upon exposure to an enzyme or laser illumination. As required, the sealant layer can be selectively removed from the top, bottom, or interior of the pores that are sealed with cells. This solves the problem of open or partly open pores in the Cell Support Membrane. Notably, a sealant layer is expected to create a total Cell Support Membrane resistance of approximately one gigaohm under any given experimental conditions. To prevent the sealant from filling the channels of the pores, the pores can be filled with a soluble composition, such as a sugar (e.g. sucrose, maltose, etc.) composition prior to the application of the sealant layer. This filler can later be removed by incubating the Cell Support Membrane with a liquid such as water, saline solution, etc.

In a preferred embodiment of the present invention, the sealant layer is positioned on the cis surface of the porous layer of the Cell Membrane Support. The sealant layer is then selectively removed from the pore openings by digestion with an enzyme that is attached to the outer face of the plasma membrane of the attached cell. In an alternate preferred embodiment, the sealant layer is positioned on the trans surface of the porous layer of the Cell Membrane Support. The sealant layer is then selectively removed from the pore openings by digestion with an enzyme that is secreted by the attached cells. Sealants that can be removed by contact with an enzyme include insoluble sugar polymers (e.g., cellulose/rayon) biodegradable polyesters, polyhydroxybutyrate, polylactate, polyglycolic acid, polycaprolactone, and extracellular matrix proteins (e.g., collagen). Suitable enzymes include, but are not limited to, enzymes that digest proteins or sugar polymers, for example, proteases, cellulases, esterases, and depolymerases. Several of such enzyme-encoding genes have been identified and isolated (see G. Smant et al., 1998, Proc. Natl. Acad. Sci. USA 95: 4906-11; K. Ota et al., 1998, Kidney Int. 54:131-42; T. Iwata et al., 1999, Int. J. Biol. Macromol. 25:169-76). In particular, membrane-associated proteases are well known in the art.

Preferably, the enzyme can be produced by an expression vector that contains the enzyme-encoding gene and is carried by the attached cell. As an example, the carboxymethylcellulase (CMCase) gene from Cellulomonas biazotea (S. Parvez et al., 1994, Folia Microbiol. (Praha.) 39: 251-4) can be cloned, expressed, and secreted by the cells, and used to digest a cellulose (rayon) sealant layer of the Cell Support Membrane. Alternatively, the CMCase coding sequence can be fused to a single transmembrane domain (TD) coding sequence (e.g., the TD of IL-1 receptor) to produce a membrane-associated fusion protein (CMCase-TD) that can be used to digest the cellulose (rayon) sealant layer. As another example, a membrane-associated cellulase (e.g., endo-1, 4-beta-D-glucanase; F. Nicole et al., 1998, EMBO J. 17:5563-76) can be used. Techniques for cloning and expressing genes and fusion constructs are well know in the art (J. Sambrook et al., 1989, Molecular Cloning, A Laboratory Manual, Cold Spring Harbor Press, Plainview, N.Y.; F. M. Ausubel et al., Eds, 1995, Current Protocols in Molecular Biology, John Wiley and Sons, Inc., New York, N.Y.; see below).

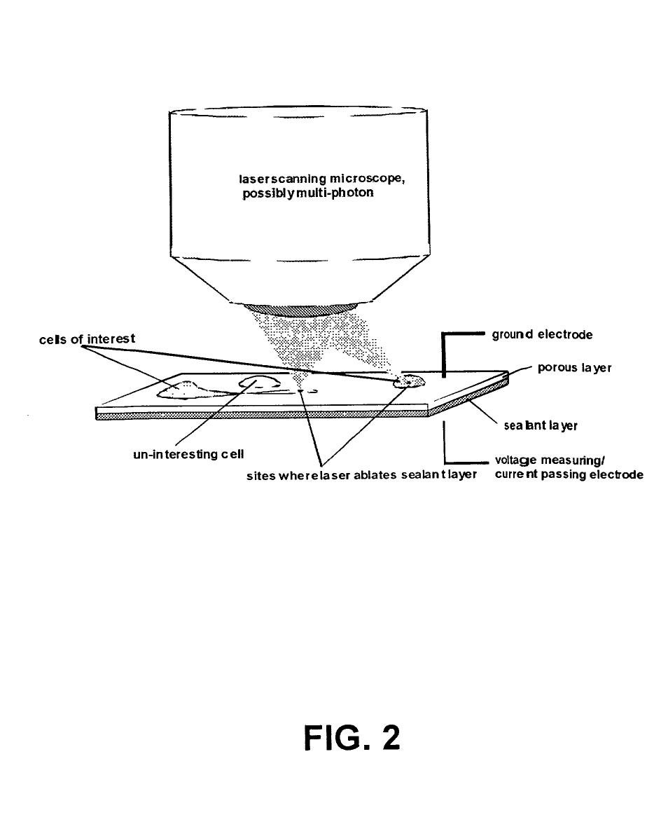

More preferably, the sealant layer is positioned under the porous layer, and is removed from the pore openings of the porous layer by microscope-assisted photo-ablation. For example, photo-ablation can be mediated by light (e.g., flash lamp or laser) sources. In particular, a laser can be put under the control of a computer and microscope (FIG. 2). This allows visual detection of the cells and pores, and can be used to direct the laser source to the region of the sealant layer directly below the pore/cell attachment site. In addition, this technique allows the identification and targeting of specific cell types for investigation based on cell morphology and/or the expression of markers, such as green fluorescent protein (GFP). Optionally, the sealant can be impregnated with a dye that can absorb the emission of the laser and thereby facilitate laser ablation. As an example, Solvent Blue 14 (oil blue N) maximally absorbs light at 637 nm and can be used in combination with the 632.8 nm line of a helium/neon laser. The exact choice of pigment will depend on the choice of the wavelength of the laser light used for a given experiment (for other examples of dyes, see F. J. Green, 1990, Sigma-Aldrich Handbook of Dyes, Stains, and Indicators, Aldrich Chemical Co., Inc., Milwaukee, Wis.).

The microscope for directing photo- (e.g., laser) ablation can be an upright or inverted scanning confocal microscope apparatus such as the Zeiss LSM 510 apparatuses (Carl Zeiss, Inc., Thornwood, N.Y.). Suitable laser sources that can be used with the microscope apparatus include, but are not limited to, YAG, argon, helium/neon, krypton gas lasers or femtosecond, pulsed titanium-sapphire laser for multi-photon excitation. Methods for the identification of cells utilizing transmitted light or epifluorescent light microscopy, and methods for the application of focused laser illumination are well known in the art. The optimal intensity and duration of laser illumination can be empirically determined for a given sealant layer. Estimates for optimal laser illumination duration and intensity can be determined by test illumination of the Cell Support Membrane sealant layer in the absence of cells. Successful removal of the sealant layer from the Cell Support Membrane can be determined by a measured decrease in resistance of the Cell Support Membrane following laser illumination.

To allow measurements of cellular electrical properties, the cis (or trans) surface of the Cell Support Membrane faces a ‘ground’ electrode, while the trans (or cis) surface of the Cell Support Membrane component faces a current-passing/voltage-measuring electrode (FIG. 1). Electrode manufacture and arrangement for electrophysiology apparatuses is well known in the art (B. Sakmann and E. Neher, 1995, Single-Channel Recording, Second Edition, Plenum Publishers, New York, N.Y.). Both cis and trans surfaces of the component are in contact with an electrolyte solution comprising, for example, HEPES buffered isotonic saline solution (140 mM NaCl, 2.5 mM KCl, 2 mM CaCl₂, 1 mM MgCl₂, 10 mM glucose, 10 mM HEPES pH 7.3; ˜290 mOsm). This arrangement allows measurements of cell membrane potential, resistance, conductance and capacitance of the cells attached to the pores of the Cell Support Membrane component using a variety of electrical configurations, e.g., cell-attached, inside-out, outside-out, whole-cell, voltage-clamp, current-clamp, and lock-in amplifier measurements (M. Lindau et al., 1988, Pflugers Arch. 411:137-46; K. D. Gillis, E. Neher et al., 1982, Proc. Natl. Acad. Sci. USA 79:6712-6).

Microchip Components

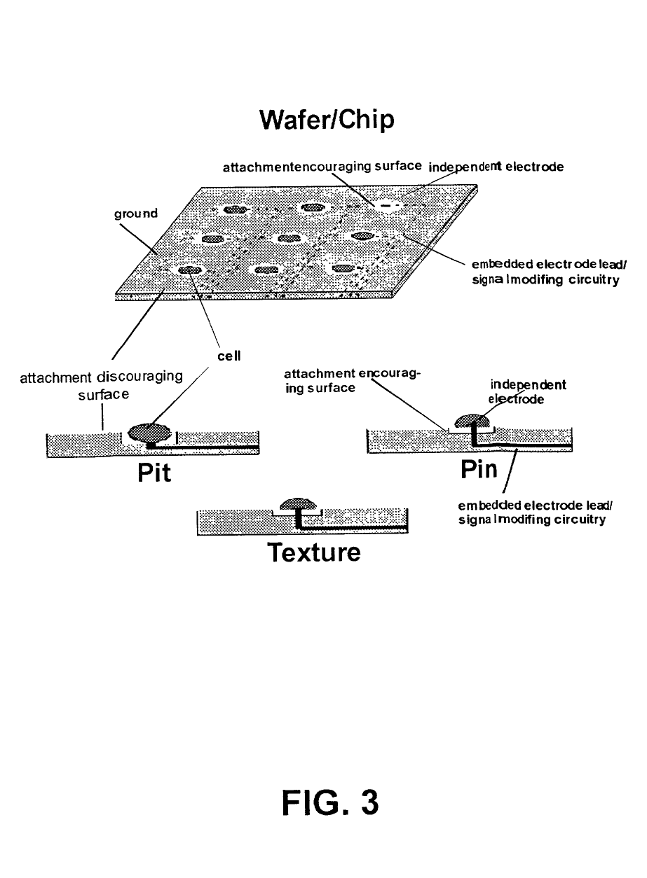

The Microchip component of the present invention comprises silicon, glass, or polymer materials. More preferably, the cis surface of the Microchip component comprises one or more features (e.g., pits, textures, pins, or cell-adhesive substances) to promote cell contact and seal formation at specific cell attachment sites, while the areas surrounding these sites comprise a material or substance to inhibit cell attachment (FIG. 3). The diameter of the cell attachment sites on the Microchip component is approximately the same as the diameter of the cell-type to be studied (e.g., 1-30 μm in diameter). Specifically, cell attachment sites can be 15-20 μm in diameter to accommodate mammalian cells (e.g., CHO cells). In addition, the number of cell attachment sites is optimized to allow a statistically acceptable number of parallel recordings. Preferably, the Microchip component displays ≧9 cell attachment sites. More preferably, the Microchip displays 9-25 cell attachment sites.

In accordance with the present invention, pits, or recessed areas, can be formed within the areas circumscribed by the cell attachment sites of the Microchip by various methods, including laser-etching, photo-etching, casting, and physical indentation of the Microchip surface. Pits are preferably 1-5 μm deep, more preferably 1-2 μm deep. Pins can be centrally placed in the areas circumscribed by the cell attachment sites. Preferably, the pins are connected to the electrodes of the Microchip (see below), and are designed to protrude through holes in the cis surface of the Microchip, and perforate the attached cells. Pins are preferably 0.1-1 μm long, more preferably 0.5-1 μm long. Substances that promote or inhibit cell attachment are described for the Cell Support Membrane component, above. The Microchip component can range in size from 1-2 mm to 1-10 cm. Each Microchip may contain one or more cell attachment areas that are physically and electrically separated form one another to allow the analysis of test compounds

To allow measurements of cellular electrical properties, the Microchip component is embedded with a ground electrode and an electrode lead/signal modifying circuitry. Preferably, an independent ground and measuring electrodes are provided adjacent to and attached to each cell attachment site of the Microchip component, and is connected to the electrode lead/signal modifying circuitry. Importantly, this arrangement allows independent measurements of the cell membrane potential, resistance, conductance, and capacitance values of each cell attached to a cell attachment site of the Microchip component. Because each cell attachment site is connected to a separate electrode, the electrodes that are connected to empty or partly filled sites can be shut-off while taking measurements of cellular electrical properties. This obviates the requirement for filling every cell attachment site with a cell. Furthermore, as the electrodes are independent of each other, cells exhibiting desired electrical properties can be selected for study, while the remaining cells can be excluded by deactivating the corresponding electrodes. Moreover, the design of the Microchip component obviates the need for an electrolyte solution on the trans surface of the component. The Microchip component therefore represents an important advancement in the design of electrophysiology devices.

Automated Electrophysiology Apparatuses

In another embodiment of the present invention, the Cell Support Membrane and Microchip components are adapted for use in automated electrophysiology recording apparatuses. Automation increases the speed and throughput of electrophysiological experiments while reducing errors associated with manual manipulations and waveform analysis. In particular, automation enables the precise timing of agent application (e.g., the addition of chemicals, compounds, or ligands), and improves the quality of experimental data by reducing inadvertent errors, idiosyncratic variations in protocol between different investigators, and introduction of noise through manual manipulations. In addition, automated waveform analysis reduces measurement errors as well as the post-processing time necessary for the analysis of experimental data, while enabling real-time evaluation of results. Because the efficiency and speed of testing is increased, automation allows mass, parallel screenings of large chemical, compound, or ligand libraries. This is especially advantageous for screening agents that affect cellular electrical properties (e.g., cell membrane conditions).

In a preferred embodiment of the present invention, the components are assembled into a multi-well plate recording apparatuses. Preferably, this apparatus accommodates 96- to 384-well plates. More preferably, the multi-well plates contain a high density of wells. This reduces the amount of test chemical, compound, or ligand that is required during testing. For processing the multi-well plates, a workstation designed to interface with commercially available robots and plate processors can be utilized. Alternatively, processing can be performed by a fully integrated stand-alone apparatus that provides plate handling, solution changes and recording capability. This apparatus is particularly advantageous since automated multi-well liquid handling equipment and robotics are commercially available.

The multi-well plate recording apparatus can be controlled by one of many types of computer utilizing instrumentation control software. Such software provides a sophisticated graphical environment that facilitates the development of virtual instruments that can be used for data acquisition and instrument control. Preferably, the software or automation routine integrates test chemical, compound, or ligand delivery, instrument control, data acquisition, and waveform analysis through an on-screen, mouse-driven interface. In this way, all aspects of the electrophysiology recording session can be controlled through the on-screen interface by using the mouse to adjust instrument controls. For example, automated protocols can be developed to initiate and carry out dose-response, reversal potential, modulator effect and repetitive application experiments with a single keypress. In addition, waveform analysis routines can automatically measure parameters such as response amplitude, onset time, and desensitization time constant, and then save this information directly to a disk. Computer software for controlling and monitoring automated cell electrophysiology apparatuses has been described in detail (see, for example, U.S. Pat. No. 6,048,722 to Farb et al.), and is well known in the art.

Data Acquisition for Electrophysiology Apparatuses

In accordance with the present invention, the disclosed electrophysiology apparatuses utilize multiple headstage preamplifiers to obtain simultaneous recording from all of the electrodes of the Cell Support Membrane or Microchip components. Preferably, the electrophysiology apparatuses utilize amplifiers that are designed to process multichannel data and facilitate simultaneous recordings (U.S. Pat. No. 6,048,722 to Farb et al.). These amplifiers can be connected to electrodes placed in close proximity to the cis and trans faces of the Cell Support Membrane or microelectrodes incorporate into the Microchip. Current, voltage, and capacitance recordings are acquired from each amplifier, data filtering and analog to digital processing are applied, and the data are stored on a computer. Following data acquisition, automated routines perform waveform analysis on each recording, utilizing well-established methods in the art.

Cells for use with Electrophysiology Components and Apparatuses

In accordance with the present invention, numerous cell types are compatible with the electrophysiology components and apparatuses described herein. Non-limiting examples of cell-types include cells derived from primary neuronal tissue, such as hippocampus, dorsal root ganglia, superior cervical ganglia tissue, and cells derived from skeletal muscle, smooth muscle, cardiac muscle, immune system, epithelial, and endothelial tissue. In particular, cell lines, such as CHO, COS, HEK-293 cell lines, which are stably or transiently transfected with one or more DNA constructs directing the expression of factors that may change the resistive, capacitive, conductive, or transmembrane voltage properties of the cells (e.g., ion channel proteins, ion transporters, G-proteins, G-protein ligands, G-protein modulators, G-protein receptors, membrane receptors, protein kinases, and/or protein phosphatases) can be used. Preferably, cells that exhibit cell membrane ion channels (e.g., sodium, potassium, calcium, and chloride voltage-gated ion channels) are used. Notably, the apparatuses of the present invention provide a distinct advantage over previous electrophysiology apparatuses designed to measure the electrical activity of multiple cells simultaneously in that they do not require the cells for study to form tight junctions with each other.

DNA constructs directing the expression of factors that modulate the electrical properties of the cells can be constructed using established methods (Sambrook et al., supra; Ausubel et al., supra). Such constructs comprise a nucleic acid encoding at least one factor that is operably linked to at least one regulatory sequence. “Operably linked” is intended to mean that the nucleotide acid sequence is linked to a regulatory sequence in a manner that allows expression of the nucleotide sequence. Regulatory sequences are known in the art and are selected to direct expression of the desired protein in an appropriate host cell. Accordingly, the term regulatory sequence includes promoters, enhancers and other expression control elements (see D. V. Goeddel, 1990, Methods Enzymol. 185:3-7). It should be understood that the design of the expression vector may depend on such factors as the choice of the host cell to be transfected and/or the type of polypeptide or peptide desired to be expressed.

Non-limiting examples of bacterial promoters include the β-lactamase (penicillinase) promoter; lactose promoter; tryptophan (trp) promoter; araBAD (arabinose) operon promoter; lambda-derived P₁ promoter and N gene ribosome binding site; and the hybrid tac promoter derived from sequences of the trp and lac UV5 promoters. Non-limiting examples of yeast promoters include the 3-phosphoglycerate kinase promoter, glyceraldehyde-3-phosphate dehydrogenase (GAPDH) promoter, galactokinase (GAL1) promoter, galactoepimerase promoter, and alcohol dehydrogenase (ADH1) promoter. Suitable promoters for mammalian cells include, without limitation, viral promoters, such as those from Simian Virus 40 (SV40), Rous sarcoma virus (RSV), adenovirus (ADV), cytomegalovirus (CMV), and bovine papilloma virus (BPV). Preferred replication and inheritance systems include M13, ColE1, SV40, baculovirus, lambda, adenovirus, CEN ARS, 2 μm ARS and the like.

Eukaryotic cells may also require terminator sequences, polyadenylation sequences, and enhancer sequences that modulate gene expression. Sequences that cause amplification of the gene may also be desirable. These sequences are well known in the art. Furthermore, sequences that facilitate secretion of the recombinant product from cells, including, but not limited to, bacteria, yeast, and animal cells, such as secretory signal sequences and/or preprotein or proprotein sequences may also be included. Such sequences are well described in the art. For some purposes, it may be preferable to produce a fusion construct comprising the coding sequence of the factor of interest and an exogenous coding sequence. In particular, exogenous sequences can be added to allow visual detection (e.g., GFP, luciferase) or localization (e.g., nuclear localization signal, secretory signal, transmembrane domain) of the fusion protein.

Prokaryotic and eukaryotic vectors and host cells may be employed. The particular choice of a vector, host cell, or translation system is not critical to the practice of the invention. DNA sequences can be optimized, if desired, for more efficient expression in a given host organism. For example, codons can be altered to conform to the preferred codon usage in a given host cell or cell-free translation system using techniques routinely practiced in the art. Suitable expression vectors include, but are not limited to, pUC, pBluescript (Stratagene, La Jolla, Calif.), pET (Novagen, Inc., Madison, Wis.), and pREP (Invitrogen Corp., San Diego, Calif.) plasmids. Vectors can contain one or more replication and inheritance systems for cloning or expression, one or more markers for selection in the host, e.g. antibiotic resistance, and one or more expression cassettes. The inserted coding sequences can be synthesized by standard methods, isolated from natural sources, or prepared as hybrids. Ligation of the coding sequences to transcriptional regulatory elements (e.g., promoters, enhancers, and/or insulators) and/or to other amino acid encoding sequences can be carried out using established methods.

Host cells for recombinant cloning vectors include bacterial, archebacterial, fungal, plant, insect and animal cells, especially mammalian cells. Of particular interest are E. coli, B. subtilis, S. aureus, S. cerevisiae, S. pombe, N. crassa, SF9, C129, 293, NIH 3T3, CHO, COS, and HeLa cells. Such cells can be transformed, transfected, or transduced, as appropriate, by any suitable method including electroporation, CaCl₂-, LiCl-, LiAc/PEG-, spheroplasting-, Ca-Phosphate, DEAE-dextran, liposome-mediated DNA uptake, injection, microinjection, microprojectile bombardment, or other established methods. To identify host cells that contain the expression vector, a gene that contains a selectable marker is generally introduced into the host cells along with the gene of interest. Preferred selectable markers include those that confer resistance to drugs, such as G418, hygromycin, methotrexate, or ampicillin. Selectable markers can be introduced on the same plasmid as the gene of interest. Host cells containing the gene of interest are identified by drug selection, as cells that carry the drug-resistance marker survive in growth media containing the corresponding drug. The surviving cells can be screened for production of the recombinant factors or fusions thereof.

In one embodiment of the present invention, cells with or without DNA constructs are permeabilized to provide access to the interior of the cells and to thereby allow measurements of internal electrical conditions. Permeabilization allows the use of whole-cell voltage-clamp, and current-clamp electrophysiology techniques. In addition, permeabilization allows the chemical composition of the cytosol to be exchanged for various test solutions. As one example, cells can be permeabilized upon contact with an antibiotic (e.g., amphotericin or nystatin). Typically, 240 μg/ml amphotericin is used for perforated patch recording of mammalian cells with standard electrophysiology equipment. However, the optimal concentration of antibiotic can be determined empirically for a given cell-type and experiment. Alternatively, cells can be permeabilized by incubation with detergent solution (e.g., digitonin or saponin), physical disruption using a high voltage field (electropermeabilization), or enzymatic digestion of a region of the cell membrane (see http://www.axon.com/MR_Axon_Guide.html). Notably, electropermeabilization can be used to permabilize the plasma membrane, without affecting the integrity of the mitochondria or endoplasmic reticulum membranes. Furthermore, electropermeabilization techniques can be precisely controlled, and do not necessitate a change of solutions following permeabilization.

Methods Utilizing Electrophysiology Apparatuses

In accordance with the present invention, the electrophysiology apparatuses and methods disclosed herein are used in screens to identify agents or processes that affect cellular electrical properties. Non-limiting examples of agents that can be identified include neurotransmitters, neurotransmitter analogues, enzyme inhibitors, ion channel modulators, G-proteins and their ligands, modulators, and receptors, transport inhibitors, hormones, peptides, toxins, antibodies, pharmaceutical agents, chemicals, and any combination of these agents. Specific agents that are of interest include purinergics, cholinergics, serotonergics, dopaminergics, anesthetics, benzodiazepines, barbiturates, steroids, alcohols, metal cations, cannabinoids, cholecystokinins, cytokines, excitatory amino acids, GABAergics, gangliosides, histaminergics, melatonins, neuropeptides, neurotoxins, endothelins, NO compounds, opioids, sigma receptor ligands, somatostatins, tachykinins, angiotensins, bombesins, bradykinins, prostaglandins and any combination of these agents.

Cellular processes that may be identified by the screens disclosed herein include cell-cell interaction, cell-cell fusion, viral infection, endocytosis, exocytosis, membrane recycling, and membrane-ligand. As all cellular process can cause a measurable change in one or more of the electrical properties of the cell, the present invention can be used to study any such process. In turn, these studies can be used to discover compounds that modulate cellular processes.

In one embodiment, the screens of the present invention utilize methods comprising the steps of: i) attaching cells to the Cell Support Membrane or Microchip components, wherein the components are inside the wells of multi-well plates, and each well is connected to a ground electrode and recording device; ii) contacting the cells with a physiologically acceptable solution; iii) (optional) contacting the cells with a permeabilization solution and then washing the cells with the physiologically acceptable solution; iv) contacting the cells with a solution containing one or more test agents and then washing the cells with the physiologically acceptable solution; and v) measuring the electrical resistance, potential, conductance, or capacitance values determined by the recording and reference electrodes.

Preferably, the screens according to the present invention are operated via automated, computer-controlled equipment. For example, the screens might utilize commercially available 96-well plates and the computer-controlled equipment for processing these plates. More preferably, the screens according to the present invention utilize multiple recording elements that are multiplexed to a data-acquisition apparatus by multiple voltage-clamp amplifiers. Such amplifiers can also be used in current-clamp, or phase-locked amplifier mode. This arrangement provides extremely high time-resolution, and allows virtually simultaneous measurement from all wells. Most preferably, the screens use very small volumes of solutions to contact the Cell Support Membrane or Microchip components that are attached with cells, e.g., 50-500 μl. This allows rapid washing steps before and after the addition of the permeabilization or test agent solutions and minimizes the amounts of test agents required for the screens. It is predicted that such screens may be used to test greater than 150,000 compounds per week.

In another embodiment of the present invention, the methods disclosed herein can be used to identify test agents that affect the function (i.e., increase or decrease the activity) of previously identified modulators of cell membrane or cell ion channel activity. Test agents can be added to cells attached to the Cell Support Membrane or Microchip components of the present invention to determine their effects on the electrical properties of the cells. Solutions comprising test agents can be pipetted or perfused onto the cis or trans surface of the Cell Support Membrane component. For the Microchip component, solutions comprising test agents can be pipetted or perfused onto the cis surface of the component.

Notably, the apparatuses and methods of the present invention can be used to obtain several different types of electrical measurements. The cell-attached configuration is shown in FIG. 1. A perforated-patch whole cell recording configuration can be obtained by adding an permeabilization solution (e.g., amphotericin B) to the trans surface of the Cell Support Membrane or Microchip component. A standard whole cell configuration can be obtained by applying a high-voltage pulse to the cell membrane to disrupt the section of membrane occluding the pore/electrode. An inside patch configuration can be obtained by lysing the cells with an air-water interface, and leaving a patch of membrane in contact with the pore/electrode.

It is further noted that the methods and apparatuses of the present invention have several advantages over pre-existing electrophysiology apparatuses. Specifically, the present invention provides strategies for preventing open or partly-open pores in a Cell Support Membrane by i) photo- (e.g., laser) ablation of the sealant layer opposite from cell attachment sites; ii) enzyme digestion of the sealant layer at cell attachment sites; or iii) plugging pores by the addition of disclosed compositions. Moreover, the present invention obviates the need for cell-sealed pores by providing a Microchip component that employs individual electrodes at each cell attachment site.

Importantly, the disclosed apparatuses do not require spatial precision for positioning the electrodes or fabricating glass pipettes. This allows rapid and trouble-free establishment of electrical measurements. In addition, the disclosed methods can be performed in temperature- and atmosphere-controlled environments. This allows more accurate approximation of physiological buffers, gas exchange, and temperatures required by the cells for study. Furthermore, the disclosed apparatuses provide a much greater degree of mechanical stability to the electrophysiological recording process. This allows the utilization of standard bench-top instrumentation, which permits analysis of cells that are traditionally difficult to study, such as actively beating cardiac myocytes. Moreover, the disclosed apparatuses and methods are ideally suited to multiplexing, which allows multiple channel recording and high-throughput screening of various chemical, agent, or ligand libraries.

### EXAMPLES

This invention is further illustrated by the following examples, which should not be construed as limiting. The contents of all references and published patent applications cited throughout this application are hereby incorporated by reference.

### Example 1

Cell Support Membrane components are constructed from polycarbonate to be 2 mm or 5 mm in diameter, and to have ˜1-20 μm thickness, 0.2-2 μm-diameter pores, and 15-20 μm-diameter cell attachment sites. The 2 mm diameter Cell Support Membranes are sized to fit 384-well microtiter plates, while the 5 mm diameter Cell Support Membranes are sized to fit 96-well microtiter plates. Cell Support Membranes are perforated by particle bombardment at a density of 10 holes per 2 mm of Membrane surface. The cell attachment sites on the cis surface of the Cell Support Membrane are treated with poly-L-lysine (0.01%) to facilitate cell attachment at the pores. The remaining cis surface of the Cell Support Membrane is treated with C18 silane (99.8%) to inhibit cell attachment outside of the cell attachment sites.

### Example 2

The Cell Support Membrane component is placed in a microtiter well, and an electrolyte solution containing 140 mM NaCl, 2.5 mM KCl, 2 mM CaCl₂, 1 mM MgCl₂, 10 mM glucose, 10 mM HEPES pH 7.3 is placed on the cis and trans surfaces of the Cell Support Membrane. Two electrodes are positioned to contact the electrolyte solution, such that the first electrode faces the cis surface of the Cell Support Membrane, while the second electrode faces the trans surface of the Cell Support Membrane. Electrodes are connected to a headstage preamplifier that is in close proximity to the Cell Support Membrane. Voltage-clamp, current-clamp, and lock-in amplification components are constructed to be remote from the headstage preamplifiers associated with the Cell Support Membranes. A lock-in amplifier (Gillis et al., supra; Neher et al., supra; Landau et al., supra) is incorporated to allow measurements of the changes in cellular capacitance that result from processes such as cell-cell interaction, viral-cell interaction, ligand-membrane interaction, cell-cell fusion, endocytosis, exocytosis, and cell receptor recycling. CHO cells are resuspended in the electrolyte solution and plated onto the cis surface of the Cell Support Membrane at high density (˜70-80% confluency) in order to maximize the chances that all the pores will be occluded by cells. The pore size and density of the Cell Support Membrane allows the cells form a seal with the pores and produce an electrically tight junction (>500 M Ohms).

### Example 3

Cell Support Membrane components are constructed and prepared as described in Examples 1 and 2. An electrolyte solution containing 140 mM NaCl, 2.5 mM KCl, 2 mM CaCl₂, 1 mM MgCl₂, 10 mM glucose, 10 mM HEPES pH 7.3 with 10 nM 20-hydroxyleukotrine B4 (a chemoattractant; Masuda et al., 1999, Biochem. J. 342:79-85) is placed on the trans surface of the Cell Support Membrane. The 20-hydroxyleukotrine B4 diffuses through the pores of the Cell Support Membrane and facilitates cell attachment at the pores on the cis surface of the Membrane. CHO-GFP10 cells expressing the leukotriene B4 (Matsuda et al., supra) are plated onto the cis surface of the Cell Support Membrane to obtain ˜70-80% confluency. The cells to form a seal with the pores, and produce an electrically tight junction (>500 M Ohms).

### Example 4

Cell Support Membrane components are constructed and processed as described in Examples 1 and 2. CHO cells are resuspended in a density gradient containing 140 mM NaCl, 2.5 mM KCl, 2 mM CaCl₂, 1 mM MgCl₂, 10 mM glucose, 10 mM HEPES pH 7.3 with 1.07-1.10 g/ml percoll. The resuspended cells are plated onto the cis surface of the Cell Support Membrane to obtain ˜70-80% confluency. The electrode facing the trans surface of the Cell Support Membrane is used to supply an electrical charge of 100 mV, which emits through the pores. The electrical field attracts the cells, and the cells adhere to the pores to form an electrically tight junction (>500 M Ohms).

### Example 5

Cell Support Membrane components are constructed and processed as described in Examples 1, 2, 3, or 4. Pores that are not sealed with an attached cell are plugged by the addition of 1 U/ml calf intestinal phosphatase onto the cis surface of the Cell Support Membrane, and the addition of 165 μg/ml BCIP (5-bromo-4-chloro-3′-indolyphosphate p-toluidine salt) and 330 μg/ml NBT (nitro-blue tetrazolium chloride) onto the trans surface of the Cell Support Membrane. The added compositions react to form a precipitate inside the pores, and the precipitate blocks the flow of electrical current through the pore channels.

### Example 6

Cell Support Membrane components are constructed from Corning Costar® Transwell-COL Cell Culture Inserts with a pore size of 0.2 μm. The trans surface of the Cell Support Membrane is sealed with a polyester sealant impregnated with 1 mM Solvent Blue 14 (oil blue N). The Cell Support Membrane is then processed as described in Example 2. CHO-GFP10 cells are resuspended in the electrolyte solution, and the resuspended cells plated onto the cis surface of the Cell Support Membrane to obtain ˜70-80% confluency. Following cell attachment, the cis surface of the Cell Support Membrane is observed using a Zeiss LSM 510 microscope in an upright configuration (Carl Zeiss, Inc.). CHO-GFP10 cells that contact the pores of the Cell Support Membrane are identified by light and fluorescence microscopy. The sealant on the trans surface of the cell-contacted pores is ablated by illumination with a 632.8 nm helium/neon laser directed by the Zeiss LSM 510 microscope apparatus (Carl Zeiss, Inc.).

### Example 7

Cell Support Membrane components are constructed from Corning Costar® Transwell-COL Cell Culture Inserts. The trans surface of the Cell Support Membrane is treated with a cellulose (rayon) sealant, which blocks the pores of the Cell Support Membrane. CHO cells are transfected with a carboxymethylcellulase gene from Cellulomonas biazotea (S. Parvez et al., 1994, Folia Microbiol. (Praha.) 39: 251-4), which is cloned into the pSI mammalian expression vector (Promega, Madison, Wis.). The transfected CHO cells are plated onto the cis surface of the Cell Support Membrane to obtain 70-80% confluency. Where cells are attached to the pores of the Cell Support Membrane, the secreted enzyme molecules diffuse through the pores to contact, digest, and remove the cellulose sealant layer. This allows electrical measurements of the attached cells.

### Example 8

Microchip components are fabricated from silicon to be 5 mm in diameter and contain 25 cell attachment sites that are connected to 25 electrodes (1 electrode per cell attachment site). The cell attachment sites on the cis surface of the Microchip are constructed to be 15-20 μm in diameter and are treated with poly-L-lysine as described in Example 1. The cis surface of the Microchip surrounding the cell attachment sites is treated with C18 silane as described in Example 1. The electrodes are fabricated as an integral part of the Microchip, so that each electrode interfaces with a single cell. A network of electrically conductive tracks is isolated from the wetted area of the Microchip by sandwich fabrication techniques. Each track is designed to terminate at a suitable external connector, allowing the application and detection of electrical signals. Localized, electrically resistive and capacitive components are incorporated to allow each electrode to be individually activated or tuned. Active semiconducting switching or rectifying elements are incorporated to allow active control and scanning of the electrodes. Local pre-amplification circuitry is incorporated to enable enhanced signal detection. A lock-in amplifier (Gillis et al., supra; Neher et al., supra; Landau et al., supra) is incorporated to allow measurements of the changes in cellular capacitance that result from cellular processes. The lock-in amplifier, current-clamp amplifier, and voltage-clamp amplifier components are constructed to be remote from the headstage preamplifiers associated with the Microchip component. CHO cells are resuspended in the electrolyte solution described in Example 2. The resuspended cells are plated onto the cis surface of the Microchip component to obtain ˜70-80% confluency. Following the attachment of the CHO cells, the electrodes are scanned to detect sites where the cells have formed a high resistance (>0.5 G Ohm) seal at the cell attachment sites.

### Example 9

Microchip components are fabricated from silicon as describe in Example 8. The cell attachment sites contain 15-20 μm diameter pits that are 1-5 μm deep, and designed to hold individual CHO cells that are described in Example 2.

### Example 10

Microchip components are fabricated from silicon as describe in Example 6. The cell attachment sites contain 0.5 μm long pins that are designed to penetrate the cell membrane of the individual CHO cells described in Example 2 following electropermeabilization of the cells using a voltage of 400 mV.

As various changes can be made in the above compositions and methods without departing from the scope and spirit of the invention, it is intended that all subject matter contained in the above description, shown in the accompanying drawings, or defined in the appended claims be interpreted as illustrative, and not in a limiting sense.

The contents of all patents, patent applications, published articles, books, reference manuals, texts and abstracts cited herein are hereby incorporated by reference in their entirety to more fully describe the state of the art to which the present invention pertains.

What is claimed is:

1. An apparatus for measuring cellular electrical conditions comprising a Cell Support Membrane component adapted to hold one or more cells which includes: i) a first layer comprising a non-conductive material comprising a top surface and bottom surface and including one or more pores, wherein the top surface of the material comprises one or more cell attachment sites which circumscribe the pores of the material and contact the cells, and wherein the pores of the material are capable of forming electrically tight seals with the contacted cells at the cell attachment sites, and ii) a second layer comprising a non-porous, nonconductive, sealant material which contacts the first layer of the Cell Support Membrane.

2. The apparatus according to claim 1, wherein the cellular electrical conditions are selected from the group consisting of transmembrane potential, capacitance, resistance, and conductance.

3. The apparatus according to claim 1, wherein the first layer of the Cell Support Membrane component comprises material selected from the group consisting of glass, plastic, rubber, polytetraflurotethylene, polytetraflurotethylene/glass, polyethylene terephthalate, and polycarbonate.

4. The apparatus according to claim 1, wherein the second layer of the Cell Support Membrane component comprises material selected from the group consisting of polytetraflurotethylene, polytetraflurotethylene/glass, polyethylene terephthalate, and polycarbonate.

5. The apparatus according to claim 1, wherein the second layer of the Cell Support Membrane component comprises material selected from the group consisting of polyhydroxybutyrate, polylactate, polyglycolic acid, polycaprolactone, cellulose, starch, and collagen.

6. The apparatus according to claim 1, wherein the second layer of the Cell Support Membrane component comprises a dye.

7. The apparatus according to claim 6, wherein the second layer of the Cell Support Membrane component comprises Solvent Blue 14.

8. The apparatus according to claim 1, wherein the cell attachment sites of the first layer of the Cell Support Membrane component are treated with a composition comprising molecules that facilitate cell attachment.

9. The apparatus according to claim 8, wherein the molecules are selected from the group consisting of gelatin, poly-L-lysine, poly-D-lysine, collagen, and fibronectin.

10. The apparatus according to claim 1, wherein an area of the first layer of the Cell Support Membrane component outside of the cell attachment sites is treated with a composition comprising molecules that inhibit cell attachment.

11. The apparatus according to claim 10, wherein the molecules are selected from the group consisting of silane, silicone, and Teflon®.

12. The apparatus according to claim 1, wherein the first layer of the Cell Support Membrane component displays at least 4 pores.

13. The apparatus according to claim 1, wherein the first layer of the Cell Support Membrane component displays 1 pore.

14. The apparatus according to claim 1, wherein the pores of the first layer of the Cell Support Membrane component are between 0.2 μm and 2 μm in diameter.

15. The apparatus according to claim 1, wherein the cells are selected from the group consisting of HEK-293 cells, Chinese hamster ovary cells, primary neuronal cells, skeletal muscle cells, smooth muscle cells, cardiac muscle cells, immune cells, epithelial cells, and endothelial cells.

16. The apparatus according to claim 15, wherein the primary neuronal cells are selected from the group consisting of hippocampus, dorsal root ganglia, and superior cervical ganglia cells.

17. The apparatus according to claim 1, wherein the cells comprise DNA constructs directing the expression of molecules selected from the group consisting of ion channel proteins, ion transporters, G-proteins, G-protein ligands, G-protein modulators, G-protein receptors, protein kinases, and protein phosphatases.

18. The apparatus according to claim 1, wherein the cells express ion channels that are specific for ions selected from the group consisting of sodium, potassium, calcium, and chloride.

19. The apparatus according to claim 1, wherein the cells are permeabilized by contact with any one of the following: i) an antibiotic selected from the group consisting of amphotericin and nystatin; ii) a detergent selected from the group consisting of digitonin and saponin; or iii) a high voltage field.

20. The apparatus according to claim 1, wherein the second layer is positioned under the first layer of the Cell Support Membrane component, and an area of the second layer of the Cell Support Membrane component that is in contact with a pore that is contacted with a cell is selectively removed.

21. The apparatus according to claim 20, wherein the area of the second layer of the Cell Support Membrane component is removed by microscope-assisted photo-ablation.

22. The apparatus according to claim 21, wherein the microscope is a confocal microscope.

23. The apparatus according to claim 21, wherein the photo-ablation is carried out with a flash lamp.

24. The apparatus according to claim 21, wherein the photo-ablation is carried out with a laser.

25. The apparatus according to claim 24, wherein the laser is selected from the group consisting of argon, helium/neon, krypton, YAG, and titanium-sapphire laser.

26. The apparatus according to claim 1, wherein the second layer is positioned over the first layer of the Cell Support Membrane component, and an area of the second layer of the Cell Support Membrane component that is in contact with a pore that is contacted with a cell is selectively removed.

27. The apparatus according to claim 26, wherein the area of the second layer of the Cell Support Membrane component is removed by an enzyme selected from the group consisting of proteases, cellulases, esterases, and depolymerases, which is secreted by the cell.

28. The apparatus according to claim 1, further comprising a chamber to hold the Cell Support Membrane component which includes a top area and bottom area, wherein the cell attachment sites of the Cell Support Membrane component face the top area of the chamber.

29. The apparatus according to claim 28, further comprising electrolyte solution which contacts the first and second layers of the Cell Support Membrane component.

30. The apparatus according to claim 29, further comprising two electrodes, Electrode 1 and Electrode 2, that are placed in the electrolyte solution, wherein one Electrode 1 is a ‘ground’ electrode and Electrode 2 is a current-passing/voltage-measuring electrode, and wherein one of the two electrodes faces the top surface of the first layer of the Cell Support Membrane component, and one of the two electrode faces the bottom surface of the first layer of the Cell Support Membrane component.

31. The apparatus according to claim 30, further comprising local pre-amplification circuitry, and a voltage-clamp, current-clamp and lock-in amplifier.

32. An apparatus for measuring cellular electrical conditions comprising a Cell Support Membrane component adapted to hold one or more cells which comprises a non-conductive material that includes a top surface and bottom surface and includes one or more pores, wherein: i) the top surface of the material comprises one or more cell attachment sites which circumscribe the pores of the material and contact the cells; ii) the pores of the material are capable of forming electrically tight seals with the contacted cells at the cell attachment sites, and iii) a pore that is not sealed with a cell is plugged by the addition of one composition to the top surface of the material, and another composition to the bottom surface of the material, such that the compositions interact in the pore and form a nonconductive solid product.

33. The apparatus according to claim 32, wherein the cellular electrical conditions are selected from the group consisting of transmembrane potential, capacitance, resistance, and conductance.

34. The apparatus according to claim 32, wherein the one composition comprises an enzyme and the other composition comprises a substrate for the enzyme.

35. The apparatus according to claim 32, wherein the one composition comprises calf alkaline phosphatase and the other composition comprises 5-bromo-4-chloro-3′-indolyphosphate p-toluidine salt and nitro-blue tetrazolium.

36. The apparatus according to claim 32, wherein the material comprising the Cell Support Membrane component is selected from the group consisting of glass, plastic, rubber, polytetraflurotethylene, polytetraflurotethylene/glass, polyethylene terephthalate, and polycarbonate.

37. The apparatus according to claim 32, wherein the cell attachment sites of the Cell Support Membrane component are treated with a composition comprising molecules that facilitate cell attachment.

38. The apparatus according to claim 37, wherein the molecules are selected from the group consisting of gelatin, poly-L-lysine, poly-D-lysine, collagen, and fibronectin.

39. The apparatus according to claim 32, wherein an area outside of the cell attachment site is treated with a composition comprising molecules that inhibit cell attachment.

40. The apparatus according to claim 39, wherein the molecules are selected from the group consisting of silane, silicone, and Teflon®.

41. The apparatus according to claim 32, wherein the Cell Support Membrane component displays at least 4 pores.

42. The apparatus according to claim 32, wherein the Cell Support Membrane component displays 1 pore.

43. The apparatus according to claim 32, wherein the pores are between 0.2 μm and 2 μm in diameter.

44. The apparatus according to claim 32, wherein the cells are selected from the group consisting of HEK-293 cells, Chinese hamster ovary cells, primary neuronal cells, skeletal muscle cells, smooth muscle cells, cardiac muscle cells, immune cells, epithelial cells, and endothelial cells.

45. The apparatus according to claim 44, wherein the primary neuronal cells are selected from the group consisting of hippocampus, dorsal root ganglia, and superior cervical ganglia cells.

46. The apparatus according to claim 32, wherein the cells comprise DNA constructs directing the expression of molecules selected from the group consisting of ion channel proteins, ion transporters, G-proteins, G-protein ligands, G-protein modulators, G-protein receptors, membrane receptors, protein kinases, and protein phosphatases.

47. The apparatus according to claim 32, wherein the cells express ion channels that are specific for ions selected from the group consisting of sodium, potassium, calcium, and chloride.

48. The apparatus according to claim 32, wherein the cells are permeabilized by contact with any one of the following: i) an antibiotic selected from the group consisting of amphotericin and nystatin; ii) a detergent selected from the group consisting of digitonin and saponin; or iii) a high voltage field.

49. The apparatus according to claim 32 , further comprising a chamber to hold the Cell Support Membrane component which includes a top area and bottom area, wherein the Cell Support Membrane component is positioned in the chamber so that the cell attachment sites of the Cell Support Membrane face the top area of the chamber.

50. The apparatus according to claim 49, further comprising electrolyte solution which contacts the first and second layers of the Cell Support Membrane component.

51. The apparatus according to claim 50, further comprising two electrodes, Electrode 1 and Electrode 2, that are placed in the electrolyte solution, wherein one Electrode 1 is a ‘ground’ electrode and Electrode 2 is a current-passing/voltage-measuring electrode, and wherein one of the two electrodes faces the top surface of the first layer of the Cell Support Membrane component, and one of the two electrode faces the bottom surface of the first layer of the Cell Support Membrane component.

52. The apparatus according to claim 51, further comprising pre-amplification circuitry and a voltage-clamp, current-clamp and lock-in amplifier.

53. An apparatus for measuring cellular electrical conditions comprising a Cell Support Membrane component adapted to hold cells which comprises a non-conductive material including a top surface and bottom surface and including one or more pores, wherein: i) the top surface of the material comprises one or more cell attachment sites which circumscribe the pores of the material and contact the cells; ii) the pores of the material are capable of forming electrically tight seals with the contacted cells at the cell attachment sites, and iii) the cells are directed to the pores by an attractant.

54. The apparatus according to claim 53, wherein the cellular electrical conditions are selected from the group consisting of transmembrane potential, capacitance, resistance, and conductance.

55. The apparatus according to claim 53, wherein the attractant is a chemoattractant.

56. The apparatus according to claim 55, wherein the chemoattractant is selected from the group consisting of growth factors, chemokines, and nutrients.

57. The apparatus according to claim 56, wherein the chemoattractant is 20-hydroxyleukotrine B4.

58. The apparatus according to claim 53, wherein the attractant is an electric field.

59. The apparatus according to claim 53, wherein the cells are resuspended in a density gradient.

60. The apparatus according to claim 59, wherein the density gradient comprises suspensions selected from the group consisting of percoll, ficoll, and metrizamide.

61. The apparatus according to claim 53, wherein the material comprising the Cell Support Membrane component is selected from the group consisting of glass, plastic, rubber, polytetraflurotethylene, polytetraflurotethylene/glass, polyethylene terephthalate, and polycarbonate.

62. The apparatus according to claim 53, wherein the cell attachment sites of the Cell Support Membrane component are treated with a composition comprising molecules that facilitate cell attachment.

63. The apparatus according to claim 62, wherein the molecules are selected from the group consisting of gelatin, poly-L-lysine, poly-D-lysine, collagen, and fibronectin.

64. The apparatus according to claim 53, wherein an area outside of the cell attachment sites is treated with a composition comprising molecules that inhibit cell attachment.

65. The apparatus according to claim 64, wherein the molecules are selected from the group consisting of silane, silicone, and Teflon®.

66. The apparatus according to claim 53, wherein the Cell Support Membrane component displays at least 4 pores.

67. The apparatus according to claim 53, wherein the Cell Support Membrane component displays 1 pore.

68. The apparatus according to claim 53, wherein the pores are between 0.2 μm and 2 μm in diameter.

69. The apparatus according to claim 53, wherein the cells are selected from the group consisting of HEK-293 cells, Chinese hamster ovary cells, primary neuronal cells, skeletal muscle cells, smooth muscle cells, cardiac muscle cells, immune cells, epithelial cells, and endothelial cells.

70. The apparatus according to claim 69, wherein the primary neuronal cells are selected from the group consisting of hippocampus, dorsal root ganglia, and superior cervical ganglia cells.

71. The apparatus according to claim 53, wherein the cells comprise DNA constructs directing the expression of molecules selected from the group consisting of ion channel proteins, ion transporters, G-proteins, G-protein ligands, G-protein modulators, G-protein receptors, membrane receptors, protein kinases, and protein phosphatases.

72. The apparatus according to claim 53, wherein the cells express ion channels that are specific for ions selected from the group consisting of sodium, potassium, calcium, and chloride.

73. The apparatus according to claim 53, wherein the cells are permeabilized by contact with any one of the following: i) an antibiotic selected from the group consisting of amphotericin and nystatin; ii) a detergent selected from the group consisting of digitonin and saponin; or iii) a high voltage field.

74. The apparatus according to claim 53, further comprising a chamber to hold the Cell Support Membrane component which includes a top area and bottom area, wherein the Cell Support Membrane component is positioned in the chamber so that the cell attachment sites of the Cell Support Membrane face the top area of the chamber.

75. The apparatus according to claim 74, further comprising electrolyte solution placed in the chamber to contact the first and second layers of the Cell Support Membrane component.

76. The apparatus according to claim 75, further comprising two electrodes, Electrode 1 and Electrode 2, that are placed in the electrolyte solution, wherein one Electrode 1 is a ‘ground’ electrode and Electrode 2 is a current-passing/voltage-measuring electrode, and wherein one of the two electrodes faces the top surface of the first layer of the Cell Support Membrane component, and one of the two electrode faces the bottom surface of the first layer of the Cell Support Membrane component.

77. The apparatus according to claim 76, further comprising pre-amplification circuitry and a voltage-clamp, current-clamp and lock-in amplifier.

78. An apparatus for measuring cellular electrical conditions comprising a Microchip component adapted to hold cells which comprises non-conductive material including a top surface and bottom surface, wherein the top surface of the material includes cell attachment sites that are sized to contact individual cells and are coupled to an electrode lead/signal modifying circuitry.

79. The apparatus according to claim 78, wherein the cellular electrical conditions are selected from the group consisting of transmembrane potential, capacitance, resistance, and conductance.

80. The apparatus according to claim 78, wherein the material of the Microarray component is selected from the group consisting of glass, silicone, plastic, rubber, polytetraflurotethylene, polytetraflurotethylene/glass, polyethylene terephthalate, and polycarbonate.

81. The apparatus according to claim 78, wherein the cell attachment sites are treated with a composition comprising molecules that facilitate cell attachment.

82. The apparatus according to claim 81, wherein the molecules are selected from the group consisting of gelatin, poly-L-lysine, poly-D-lysine, collagen, and fibronectin.

83. The apparatus according to claim 78, wherein an area surrounding the cell attachment sites is treated with a composition comprising molecules that inhibit cell attachment.

84. The apparatus according to claim 83, wherein the molecules are selected from the group consisting of silane, silicone, and Teflon®.

85. The apparatus according to claim 78, wherein the cell attachment sites include pins that are sized to penetrate the contacting cell, and wherein each pin houses an electrode connected to a headstage preamplifier.

86. The apparatus according to claim 78, wherein the cell attachment sites include pits that are sized to accommodate the contacting cells.

87. The apparatus according to claim 78, wherein the top surface of the Microchip component displays at least 9 cell attachment sites.

88. The apparatus according to claim 78, wherein the cell attachment sites are between 15 μm and 20 μm in diameter.

89. The apparatus according to claim 78, wherein the cells are selected from the group consisting of HEK-293 cells, Chinese hamster ovary cells, primary neuronal cells, skeletal muscle cells, smooth muscle cells, cardiac muscle cells, immune cells, epithelial cells, and endothelial cells.

90. The apparatus according to claim 89, wherein the primary neuronal cells are selected from the group consisting of hippocampus, dorsal root ganglia, and superior cervical ganglia cells.

91. The apparatus according to claim 78, wherein the cells comprise DNA constructs directing the expression of molecules selected from the group consisting of ion channel proteins, ion transporters, G-proteins, G-protein ligands, G-protein modulators, G-protein receptors, membrane receptors, protein kinases, and protein phosphatases.

92. The apparatus according to claim 78, wherein the cells express ion channels that are specific for ions selected from the group consisting of sodium, potassium, calcium, and chloride.

93. The apparatus according to claim 78, wherein the cells are permeabilized by contact with a high voltage field.

94. The apparatus according to claim 78, wherein a cell attachment site is adjacent to an independent ground electrode and connected to an independent measuring electrode.

95. The apparatus according to claim 78, further comprising a chamber to hold the Cell Support Membrane component which includes a top area and bottom area, wherein the Microchip component is positioned in the chamber so that the cell attachment sites of the Microchip face the top area of the chamber.

96. The apparatus according to claim 95, further comprising electrolyte solution which contacts the top surface of the Microchip component.

97. The apparatus according to claim 96, further comprising local pre-amplification circuitry and a voltage-clamp, current-clamp, and lock-in amplifier.

98. An high throughput screening method for detecting and assaying test agents that affect cellular electrical activity comprising: i) attaching cells to a plurality of apparatuses according to claim 31; ii) measuring electrical activity of the cells contacted with electrolyte solution; iii) contacting the cells with an electrolyte solution comprising a test agent; iv) measuring the electrical activity of the cells contacted with the test agent; and v) assessing a difference between the measured electrical activity in step (ii) and the measured electrical activity in step (iv).

99. The method according to claim 98, wherein the cellular electrical activity is selected from the group consisting of potential, resistance, conductance, and capacitance.

100. The method according to claim 98, wherein chambers of the apparatuses are provided by a multi-well plate.

101. The method according to claim 98, wherein the multi-well plate is processed by computer-controlled equipment.

102. The method according to claim 98, wherein the cells are selected from the group consisting of HEK-293 cells, Chinese hamster ovary cells, primary neuronal cells, skeletal muscle cells, smooth muscle cells, cardiac muscle cells, immune cells, epithelial cells, and endothelial cells.

103. The method according to claim 102, wherein the primary neuronal cells are selected from the group consisting of hippocampus, dorsal root ganglia, and superior cervical ganglia cells.

104. The method according to claim 98, wherein the cells comprise DNA constructs directing the expression of molecules selected from the group consisting of ion channel proteins, ion transporters, G-proteins, G-protein ligands, G-protein modulators, G-protein receptors, membrane receptors, protein kinases, and protein phosphatases.

105. The method according to claim 98, wherein the cells express ion channels that are specific for ions selected from the group consisting of sodium, potassium, calcium, and chloride.

106. The method according to claim 98, wherein the cells are permeabilized by contact with any one of the following: i) an antibiotic selected from the group consisting of amphotericin and nystatin; ii) a detergent selected from the group consisting of digitonin and saponin; and iii) a high voltage field.

107. The method according to claim 98, wherein the test agent is selected from the group consisting of neurotransmitters, neurotransmitter analogues, enzyme inhibitors, ion channel modulators, G-proteins, G-protein ligands, G-protein modulators, G-protein receptors, transport inhibitors, hormones, peptides, toxins, antibodies, pharmaceutical agents, and chemicals.

108. The method according to claim 98, wherein the test agent is selected from the group consisting of purinergics, cholinergics, serotonergics, dopaminergics, anesthetics, benzodiazepines, barbiturates, steroids, alcohols, metal cations, cannabinoids, cholecystokinins, cytokines, excitatory amino acids, GABAergics, gangliosides, histaminergics, melatonins, neuropeptides, neurotoxins, endothelins, NO compounds, opioids, sigma receptor ligands, somatostatins, tachykinins, angiotensins, bombesins, bradykinins, and prostaglandins.

109. A high throughput screening method for detecting and assaying cell processes that affect cellular electrical activity comprising: i) attaching cells to a plurality of apparatuses according to claim 31; ii) measuring electrical activity of cells that are in a resting state; iii) initiating the cell process; iv) measuring the electrical activity of cells engaged in the process; and v) assessing a difference between the measured electrical activity in step (ii) and the measured electrical activity in step (iv).

110. The method according to claim 109, wherein the cellular electrical activity is selected from the group consisting of potential, resistance, conductance, and capacitance.

111. The method according to claim 109, wherein chambers of the apparatuses are provided by a multi-well plate.

112. The method according to claim 109, wherein the multi-well plate is processed by computer-controlled equipment.

113. The method according to claim 109, wherein the cells are selected from the group consisting of HEK-293 cells, Chinese hamster ovary (CHO) cells, primary neuronal cells, skeletal muscle cells, smooth muscle cells, cardiac muscle cells, immune cells; epithelial cells, and endothelial cells.

114. The method according to claim 113, wherein the primary neuronal cells are selected from the group consisting of hippocampus, dorsal root ganglia, and superior cervical ganglia cells.

115. The method according to claim 109, wherein the cells comprise DNA constructs directing the expression of molecules selected from the group consisting of ion channel proteins, ion transporters, G-protein coupled receptors, membrane receptors, protein kinases, and protein phosphatases.

116. The method according to claim 109, wherein the cells express ion channels that are specific for ions selected from the group consisting of sodium, potassium, calcium, and chloride.

117. The method according to claim 109, wherein the cells are permeabilized by contact with any one of the following: i) an antibiotic selected from the group consisting of amphotericin and nystatin; ii) a detergent selected from the group consisting of digitonin and saponin; and iii) a high voltage field.

118. The method according to claim 109, wherein the test agent is selected from the group consisting of neurotransmitters, neurotransmitter analogues, enzyme inhibitors, ion channel modulators, G-proteins, G-protein ligands, G-protein modulators, G-protein receptors, transport inhibitors, hormones, peptides, toxins, antibodies, pharmaceutical agents, and chemicals.

119. The method according to claim 109, wherein the test agent is selected from the group consisting of purinergics, cholinergics, serotonergics, dopaminergics, anesthetics, benzodiazepines, barbiturates, steroids, alcohols, metal cations, cannabinoids, cholecystokinins, cytokines, excitatory amino acids, GABAergics, gangliosides, histaminergics, melatonins, neuropeptides, neurotoxins, endothelins, NO compounds, opioids, sigma receptor ligands, somatostatins, tachykinins, angiotensins, bombesins, bradykinins, and prostaglandins.

120. The method according to claim 109, wherein the cell process is selected from the group consisting of cell-cell interaction, cell-cell fusion, viral infection, endocytosis, exocytosis, membrane recycling, and membrane-ligand interaction.
